(19) United States
(12) Patent Application Publication
(10) Pub. No.: US 2020/0173054 A1
(43) Pub. Date: Jun. 4, 2020

(54) FILM FORMATION APPARATUS

(71) Applicants: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(72) Inventors: Tatsuji NAGAOKA, Nagakute-shi (JP); Hiroyuki NISHINAKA, Kyoto-shi (JP); Masahiro YOSHIMOTO, Kyoto-shi (JP)

(73) Assignees: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(21) Appl. No.: 16/697,370

(22) Filed: Nov. 27, 2019

(30) Foreign Application Priority Data
Dec. 3, 2018 (JP) 2018-226785

(51) Int. Cl. C30B 25/16; C23C 16/40; C30B 29/16; C30B 25/14; C30B 25/10

(52) U.S. Cl. CPC C30B 25/165; C23C 16/40; C30B 25/10; C30B 25/14; C30B 29/16

(57) ABSTRACT

A film formation apparatus configured to supply mist of a solution to a substrate to epitaxially grow a film on the substrate and including: a furnace housing the substrate; a mist generation tank configured to generate the mist therein; a mist supply path connecting the tank and furnace; a carrier gas supply path configured to supply carrier gas into the tank; a diluent gas supply path configured to supply diluent gas into the mist supply path; and a gas flow rate controller configured to control flow rates of the carrier and diluent gas. The mist in the tank flows to the mist supply path with the carrier gas, the mist in the mist supply path flows to the furnace with the carrier and diluent gas, and the controller is configured to decrease the flow rate of the diluent gas when increasing the flow rate of the carrier gas.

### TECHNICAL FIELD

The technology disclosed herein relates to a film formation apparatus.

### BACKGROUND

Japanese Patent Application Publication No. 2017-162816 discloses a film formation apparatus that supplies mist of a solution to a surface of a substrate so as to epitaxially grow a film on the surface of the substrate. This film formation apparatus includes a furnace configured to house the substrate so as to heat the substrate, a mist generation tank configured to generate the mist of the solution therein, a mist supply path connecting the mist generation tank and the furnace, a carrier gas supply path configured to supply carrier gas into the mist generation tank, and a diluent gas supply path configured to supply diluent gas into the mist supply path. When the carrier gas is supplied to the mist generation tank, the mist in the mist generation tank flows to the mist supply path with the carrier gas. When the diluent gas is supplied to the mist supply path, the mist in the mist supply path flows to the furnace with the carrier gas and the diluent gas. The mist that has flowed into the furnace adheres to the surface of the substrate, so that the film is epitaxially grown on the surface of the substrate.

### SUMMARY

The film formation apparatus in Japanese Patent Application Publication No. 2017-162816 can modify a concentration of the mist supplied to the furnace by modifying a flow rate of the carrier gas and/or the diluent gas. Due to this, characteristics of the film can be modified. Modifying the flow rate of the carrier gas and/or the diluent gas, however, leads to change in flow velocity of the mist in the furnace, and under influence of the change in the flow velocity of the mist, the characteristics of the film will change. This may cause difficulty in controlling the characteristics of the film to desired characteristics. Moreover, an attempt to control the concentration of the mist to a specific concentration may cause the flow velocity of the mist to deviate from an appropriate film-forming condition, thereby hindering stable growth of the film. The present specification proposes a technology of modifying a concentration of a mist in a furnace while suppressing a change in flow velocity of the mist in the furnace.

A film formation apparatus disclosed herein is configured to supply mist of a solution to a surface of a substrate so as to epitaxially grow a film on the surface of the substrate, and the film formation apparatus may comprise: a furnace housing the substrate so as to heat the substrate; a mist generation tank configured to generate the mist of the solution therein; a mist supply path connecting the mist generation tank and the furnace; a carrier gas supply path configured to supply carrier gas into the mist generation tank; a diluent gas supply path configured to supply diluent gas into the mist supply path; and a gas flow rate controller configured to control a flow rate of the carrier gas and a flow rate of the diluent gas, wherein the mist in the mist generation tank flows to the mist supply path with the carrier gas, the mist in the mist supply path flows to the furnace with the carrier gas and the diluent gas, and the gas flow rate controller is configured to decrease the flow rate of the diluent gas when increasing the flow rate of the carrier gas.

In the above film formation apparatus, the mist in the mist generation tank flows to the mist supply path with the carrier gas. A greater flow rate of the carrier gas, therefore, causes a greater amount of the mist that flows from the mist generation tank to the mist supply path. In the mist supply path, the diluent gas merges with the mist, thereby decreasing the concentration of the mist. A greater flow rate of the diluent gas, therefore, causes a lower concentration of the mist. The gas flow rate controller is configured to decrease the flow rate of the diluent gas when increasing the flow rate of the carrier gas. Due to this, the amount of the mist that flows from the mist generation tank to the mist supply path increases, and also the amount by which the concentration of the mist in the mist supply path decreases becomes smaller. Accordingly, the concentration of the mist supplied to the furnace increases. Moreover, since the flow rate of the diluent gas is reduced when the flow rate of the carrier gas is increased, the flow rate of gas supplied to the furnace remains almost unchanged. Due to this, even if the concentration of the mist supplied to the furnace increases, the flow velocity of the mist in the furnace remains almost unchanged. As such, according to this film formation apparatus, the concentration of the mist in the furnace can be increased while suppressing changes in flow velocity of the mist in the furnace. The film formation apparatus disclosed herein can achieve, therefore, accurate control of the characteristics of a film to be grown.

### BRIEF DESCRIPTION OF DRAWINGS

FIG. 1 is a configuration diagram of a film formation apparatus in a first embodiment;

FIG. 2 is a configuration diagram of a film formation apparatus in a second embodiment; and

FIG. 3 is a configuration diagram of a film formation apparatus in a third embodiment.

### DETAILED DESCRIPTION

### First Embodiment

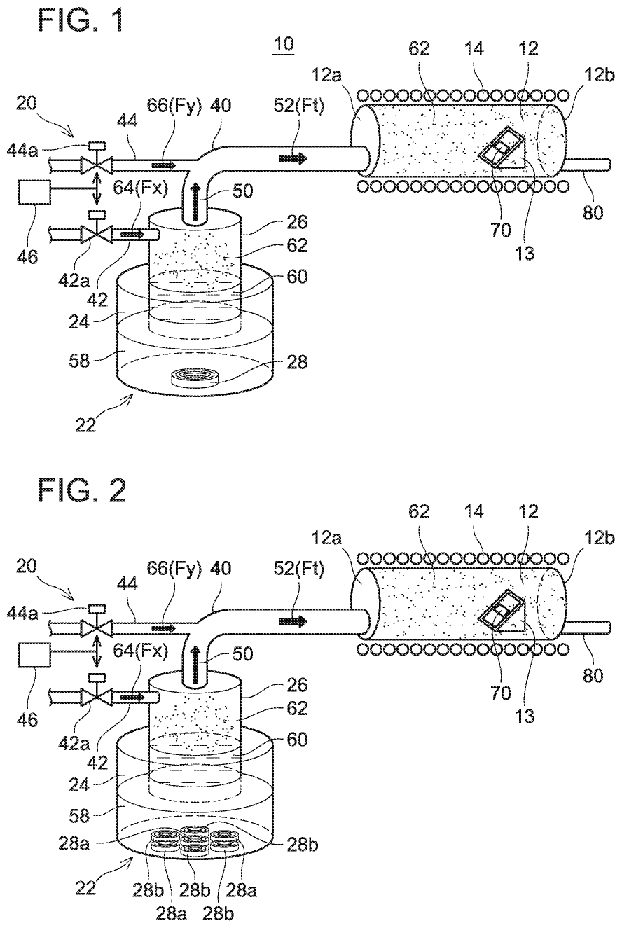

A film formation apparatus 10 shown in FIG. 1 is an apparatus configured to epitaxially grow a film on a surface of a substrate 70. The film formation apparatus 10 comprises a furnace 12 in which the substrate 70 is placed, a heater 14 configured to heat the furnace 12, a mist supply apparatus 20 connected to the furnace 12, and an exhaust pipe 80 connected to the furnace 12.

A configuration of the furnace 12 is not specifically limited to a particular one. As an example, the furnace 12 shown in FIG. 1 is a tubular furnace extending from an upstream end 12a to a downstream end 12b. A cross section of the furnace 12, perpendicular to its longitudinal direction, is circular. However, the cross section of the furnace 12 is not limited to a circular one.

The mist supply apparatus 20 is connected to the upstream end 12a of the furnace 12. The exhaust pipe 80 is connected to the downstream end 12b of the furnace 12. The mist supply apparatus 20 is configured to supply mist 62 into the furnace 12. The mist 62 that has been supplied into the furnace 12 by the mist supply apparatus 20 flows through the furnace 12 to the downstream end 12b, and is then discharged to an outside of the furnace 12 via the exhaust pipe 80.

Provided in the furnace 12 is a substrate stage 13 for supporting the substrate 70. The substrate stage 13 is configured such that the substrate 70 is tilted relative to the longitudinal direction of the furnace 12. The substrate 70 supported by the substrate stage 13 is supported in an orientation that allows the mist 62 that flows through the furnace 12 from the upstream end 12a toward the downstream end 12b to be applied on a surface of the substrate 70.

As mentioned before, the heater 14 is configured to heat the furnace 12. A configuration of the heater 14 is not specifically limited to a particular one. As an example, the heater 14 shown in FIG. 1 is an electric heater, and is placed along a peripheral wall of the furnace 12. The heater 14 heats the peripheral wall of the furnace 12, so that the substrate 70 in the furnace 12 is heated.

The mist supply apparatus 20 includes a mist generation tank 22. The mist generation tank 22 includes a water tank 24, a solution reservoir 26, and an ultrasonic transducer 28. The water tank 24 is a tank a top of which is open, and stores water 58 therein. The ultrasonic transducer 28 is disposed at a bottom of the water tank 24. The ultrasonic transducer 28 applies ultrasonic vibration to the water 58 in the water tank 24. The solution reservoir 26 is an enclosed container. The solution reservoir 26 stores a solution 60 that contains a material of a film to be epitaxially grown on the surface of the substrate 70. For example, if a gallium oxide (Ga₂O₃) film is to be epitaxially grown, a solution in which gallium is dissolved can be used as the solution 60. Moreover, a material for adding an n-type or p-type dopant to the gallium oxide film (e.g., ammonium fluoride or the like) may further be dissolved in the solution 60. The solution reservoir 26 has its bottom sunk in the water 58 in the water tank 24. A film constitutes a bottom of the solution reservoir 26. This facilitates transfer of ultrasonic vibration from the water 58 in water tank 24 to the solution 60 in the solution reservoir 26. When the ultrasonic transducer 28 applies ultrasonic vibration to the water 58 in the water tank 24, the ultrasonic vibration is transferred to the solution 60 via the water 58. A surface of the solution 60 then vibrates, so that the mist 62 of the solution 60 is generated in a space above the solution 60 (i.e., a space in the solution reservoir 26).

The mist supply apparatus 20 further includes a mist supply path 40, a carrier gas supply path 42, a diluent gas supply path 44, and a gas flow controller 46.

An upstream end of the mist supply path 40 is connected to an upper surface of the solution reservoir 26. A downstream end of the mist supply path 40 is connected to the upstream end 12a of the furnace 12. The mist supply path 40 supplies the mist 62 from the solution reservoir 26 to the furnace 12.

A downstream end of the carrier gas supply path 42 is connected to an upper portion of a side surface of the solution reservoir 26. An upstream end of the carrier gas supply path 42 is connected to a carrier gas supply source not shown. The carrier gas supply path 42 supplies carrier gas 64 from the carrier gas supply source to the solution reservoir 26. The carrier gas 64 is nitrogen gas or another inert gas. The carrier gas 64 that has flowed into the solution reservoir 26 flows from the solution reservoir 26 to the mist supply path 40. At this occasion, the mist 62 in the solution reservoir 26 flows to the mist supply path 40 with the carrier gas 64. A greater flow rate Fx (L/min) of the carrier gas 64, therefore, causes a greater amount of the mist 62 that flows from the solution reservoir 26 to the mist supply path 40. The carrier gas supply path 42 has a flow control valve 42a interposed therein. The flow control valve 42a is configured to control the flow rate Fx of the carrier gas 64 in the carrier gas supply path 42.

A downstream end of the diluent gas supply path 44 is connected to some midpoint of the mist supply path 40. An upstream end of the diluent gas supply path 44 is connected to a diluent gas supply source not shown. The diluent gas supply path 44 supplies diluent gas 66 from the diluent gas supply source to the mist supply path 40. The diluent gas 66 is nitrogen gas or another inert gas. The diluent gas 66 that has flowed into the mist supply path 40 flows to the furnace 12 with the mist 62 and the carrier gas 64. The mist 62 in the mist supply path 40 is diluted by the diluent gas 66. A greater flow rate Fy (L/min) of the diluent gas 66, therefore, causes a lower concentration of the mist 62 supplied to the furnace 12. The diluent gas supply path 44 has a flow control valve 44a interposed therein. The flow control valve 44a is configured to control the flow rate Fy of the diluent gas 66 in the diluent gas supply path 44.

The gas flow controller 46 is electrically connected to the flow control valves 42a, 44a. The gas flow controller 46 controls the flow control valves 42a, 44a so as to control the flow rate Fx of the carrier gas 64 and the flow rate Fy of the diluent gas 66.

Next, a film formation method using the film formation apparatus 10 will be described. Here, a substrate constituted of a single crystal of β-gallium oxide (β-Ga₂O₃) is used as the substrate 70. Moreover, an aqueous solution in which gallium chloride (GaCl₃, Ga₂Cl₆) and ammonium fluoride (NH₄F) are dissolved is used as the solution 60. Moreover, nitrogen gas is used as the carrier gas 64, and nitrogen gas is used as the diluent gas 66.

At first, the substrate 70 is arranged on the substrate stage 13 in the furnace 12. Next, the substrate 70 is heated by the heater 14. Here, a temperature of the substrate 70 is controlled to approximately 750° C. When the temperature of the substrate 70 is stabilized, the mist supply apparatus 20 is activated. In other words, the ultrasonic transducer 28 is activated so as to cause the mist 62 of the solution 60 to be generated in the solution reservoir 26. Simultaneously, the carrier gas 64 is introduced from the carrier gas supply path 42 into the solution reservoir 26, and the diluent gas 66 is introduced from the diluent gas supply path 44 into the mist supply path 40. Here, the flow rate Fx of the carrier gas 64 and the flow rate Fy of the diluent gas 66 are respectively controlled to certain values by the gas flow controller 46. Here, a total flow rate Ft of the flow rate Fx and the flow rate Fy is set to approximately 5 L/min. The carrier gas 64 passes through the solution reservoir 26, and as shown by an arrow 50, flows into the mist supply path 40. At this occasion, the mist 62 in the solution reservoir 26 flows into the mist supply path 40 with the carrier gas 64. Moreover, the diluent gas 66 is mixed with the mist 62 in the mist supply path 40. The mist 62 is thereby diluted. The mist 62, together with the nitrogen gas (i.e., the carrier gas 64 and the diluent gas 66), flows downstream through the mist supply path 40, and as shown by an arrow 52, flows from the mist supply path 40 into the furnace 12. In the furnace 12, the mist 62 flows toward the downstream end 12b with the nitrogen gas, and is discharged to the exhaust pipe 80.

A part of the mist 62 that flows through the furnace 12 adheres to the surface of the substrate 70 that has been heated. A chemical reaction of the mist 62 (i.e., the solution 60) then occurs on the substrate 70. As a result, β-gallium oxide (β-Ga₂O₃) is generated on the substrate 70. The mist 62 is continuously supplied to the surface of the substrate 70 so that a β-gallium oxide film is grown on the surface of the substrate 70. A single-crystal β-gallium oxide film is grown on the surface of the substrate 70. If the solution 60 contains a material of a dopant, the dopant is captured in the β-gallium oxide film. For example, if the solution 60 contains ammonium fluoride, a β-gallium oxide film doped with fluorine is formed.

A film quality of the gallium oxide film changes depending on the concentration of the mist 62 supplied to the surface of the substrate 70 and a flow velocity (m/sec) of the mist 62 in the furnace 12. A lower concentration of the mist 62 causes a slower growth speed of the gallium oxide film, whereas a higher concentration of the mist 62 causes a faster growth speed of the gallium oxide film. The concentration of the mist 62 (i.e., growth speed of the gallium oxide film) affects the film quality of the gallium oxide film. Moreover, a higher flow velocity of the mist 62 causes the mist 62 to impinge on the surface of the substrate 70 at a higher velocity, and a growth condition of the gallium oxide film changes in accordance with the flow velocity of the mist 62. The flow velocity of the mist 62, therefore, affects the film quality of the gallium oxide film. The film formation apparatus 10 is capable of modifying the concentration of the mist 62 in the furnace 12 during a course of the film-forming process. At this occasion, as described below, the film formation apparatus 10 modifies the concentration of the mist 62 while keeping the flow velocity of the mist 62 in the furnace 12 almost unchanged.

When the concentration of the mist 62 to be supplied to the furnace 12 is to be increased, the gas flow controller 46 controls the flow control valves 42a, 44a so as to increase the flow rate Fx of the carrier gas 64 and decrease the flow rate Fy of the diluent gas 66. The increase in the flow rate Fx of the carrier gas 64 means an increase in amount of the mist 62 that flows from the mist generation tank 22 to the mist supply path 40. The decrease in the flow rate Fy of the diluent gas 66 means a reduction in amount by which the concentration of the mist 62 in the mist supply path 40 decreases. Therefore, the increase in the flow rate Fx of the carrier gas 64 and the decrease in the flow rate Fy of the diluent gas 66 cause an increase in concentration of the mist 62 supplied to the furnace 12. Moreover, since the flow rate Fx of the carrier gas 64 increases and the flow rate Fy of the diluent gas 66 decreases, the total flow rate Ft of the carrier gas 64 and the diluent gas 66 (=Fx+Fy) remains almost unchanged. For example, resultant changes in total flow rate Ft before and after the increase of the flow rate Fx are controlled to fall within a range from −10% to +10%. As such, by decreasing the change in total flow rate Ft, a change in flow velocity of the mist 62 in the furnace 12 can be made smaller. As such, the film formation apparatus 10 can increase the concentration of the mist 62 to be supplied to the furnace 12 while suppressing change in flow velocity of the mist 62 in the furnace 12. Due to this, the film quality can be changed by increasing the concentration of the mist 62 while suppressing the influence on the film quality caused by the change in flow velocity of the mist 62. The film quality of the gallium oxide film can therefore be controlled accurately. To keep the total flow rate Ft unchanged before and after the process of increasing the concentration of the mist 62, in particular, an amount by which the flow rate Fx is increased and an amount by which the flow rate Fy is decreased may be equalized. Since unchanged total flow rate Ft also allows unchanged flow velocity of the mist 62 in the furnace 12, the influence on the film quality caused by the change in flow velocity of the mist 62 can be minimized. The film quality of the gallium oxide film can thereby be controlled more accurately.

When the concentration of the mist 62 to be supplied to the furnace 12 is to be decreased, the gas flow controller 46 controls the flow control valves 42a, 44a so as to decrease the flow rate Fx of the carrier gas 64 and increase the flow rate Fy of the diluent gas 66. The decrease in the flow rate Fx of the carrier gas 64 causes a decrease in the amount of the mist 62 that flows from the mist generation tank 22 to the mist supply path 40. The increase in the flow rate Fy of the diluent gas 66 causes an increase in amount by which the concentration of the mist 62 in the mist supply path 40 decreases. Therefore, the decrease of the flow rate Fx of the carrier gas 64 and the increase of the flow rate Fy of the diluent gas 66 cause a decrease of the concentration of the mist 62 supplied to the furnace 12. Moreover, since the flow rate Fx of the carrier gas 64 decreases and the flow rate Fy of the diluent gas 66 increases, the total flow rate Ft of the carrier gas 64 and the diluent gas 66 (=Fx+Fy) remains almost unchanged. For example, resultant changes in total flow rate Ft before and after the decrease in flow rate Fx are controlled to fall within a range from −10% to +10%. As such, by making the changes in total flow rate Ft smaller, the changes in flow velocity of the mist 62 in the furnace 12 can be made smaller. As such, the film formation apparatus 10 can decrease the concentration of the mist 62 to be supplied to the furnace 12 while suppressing the changes in flow velocity of the mist 62 in the furnace 12. Due to this, the film quality can be changed by decreasing the concentration of the mist 62 while suppressing the influence on the film quality caused by the change in flow velocity of the mist 62. The film quality of the gallium oxide film can therefore be controlled accurately. To keep the total flow rate Ft unchanged before and after the process of decreasing the concentration of the mist 62, in particular, an amount by which the flow rate Fx is decreased and an amount by which the flow rate Fy is increased may be equalized. Since unchanged total rate Ft also allows the flow velocity of the mist 62 in the furnace 12 to remain unchanged, the influence on the film quality caused by the change in flow velocity of the mist 62 can be minimized. The film quality of the gallium oxide film can thereby be controlled more accurately.

As described above, according to the film formation apparatus 10 in the first embodiment, the concentration of the mist 62 in the furnace 12 can be changed while suppressing the changes in flow velocity of the mist 62 in the furnace 12. The characteristics of the film to be grown can thereby be controlled accurately. For example, change in flow velocity of the mist 62 causes change in growth rate of the gallium oxide film, and change in concentration of the dopant with which the gallium oxide film is doped. By suppressing the changes in flow velocity of the mist 62, the change in concentration of the dopant can be suppressed. Moreover, it is possible to keep the flow velocity of the mist 62 from deviating from an appropriate film-forming condition when the concentration of the mist 62 is changed. For example, if the flow velocity of the mist 62 is excessively high, epitaxial growth of a gallium oxide film is hindered. Such a problem can be prevented by suppression of the change in flow velocity of the mist 62.

In the above-mentioned embodiment, the case of growing a gallium oxide film has been described as an example. However, the film to be grown can be suitably selected. Moreover, the materials for the solution 60 and the substrate 70 can be suitably selected in accordance with a film to be grown.

### Second Embodiment

Next, a film formation apparatus in second embodiment will be described. In the second embodiment, a mist supply apparatus 20 comprises a plurality of ultrasonic transducers 28. Other configurations of the film formation apparatus in the second embodiment are the same as the configurations of the film formation apparatus 10 in the first embodiment.

The plurality of ultrasonic transducers 28 in the second embodiment is grouped into a first group of ultrasonic transducers 28a and a second group of ultrasonic transducers 28b. The ultrasonic transducers 28 are controlled on a group-by-group basis.

Next, a film formation method using the film formation apparatus in the second embodiment will be described. At first, as in the first embodiment, the substrate 70 is set on the substrate stage 13 in the furnace 12, and heated by the heater 14. When the temperature of the substrate 70 has stabilized, the mist supply apparatus 20 is activated to start an epitaxial growth step. Here, the first group of ultrasonic transducers 28a is activated while the second group of ultrasonic transducers 28b is not activated. The first group of ultrasonic transducers 28a operates so as to generate the mist 62 of the solution 60 in the solution reservoir 26. Simultaneously, the carrier gas 64 is introduced from the carrier gas supply path 42 into the solution reservoir 26, and the diluent gas 66 is introduced from the diluent gas supply path 44 into the mist supply path 40. Due to this, as shown by the arrow 52, the mist 62 is supplied to the furnace 12 with the carrier gas 64 and the diluent gas 66. After a lapse of a certain time period since the activation of the first group of ultrasonic transducers 28a, the second group of ultrasonic transducers 28b is additionally activated. In other words, while the first group of ultrasonic transducers 28a is continuously activated, the second group of ultrasonic transducers 28b is activated. Due to this, energy of ultrasonic vibration applied to the solution 60 in the solution reservoir 26 increases, and the mist 62 generated in the solution reservoir 26 increases. The concentration of the mist 62 in the furnace 12 accordingly increases. As such, activating the two groups of ultrasonic transducers 28a, 28b in a stepwise manner can gently increase the concentration of the mist 62 in the furnace 12 at beginning of the epitaxial growth step.

At the beginning of the epitaxial-growth step, the substrate 70 is exposed to the mist 62, and heat of the substrate 70 is drawn away by the mist 62. Consequently, the temperature of the substrate 70 decreases. There may be a case where a rapid rise in concentration of the mist 62 in the furnace 12 causes a rapid drop in temperature of the substrate 70, resulting in the grown film having undesired characteristics. In contrast to this, by gently increasing the concentration of the mist 62 in the furnace 12 at the beginning of the epitaxial growth step, as described above, the temperature of the substrate 70 will gently drop, resulting in stable characteristics of the film.

During the epitaxial growth step, the film formation apparatus in the second embodiment, similarly to the film formation apparatus in the first embodiment, is capable of changing the concentration of the mist 62 in the furnace 12 by the gas flow controller 46.

When the epitaxial growth step is to be ended, one of the groups of ultrasonic transducers 28a, 28b is stopped first. The mist 62 generated in the solution reservoir 26 then decreases, and the concentration of the mist 62 in the furnace 12 decreases. Then, after a lapse of a certain time period, the other of the groups of ultrasonic transducers 28a, 28b is stopped. The generation of the mist 62 in the solution reservoir 26 is then stopped, so that the concentration of the mist 62 in the furnace 12 drops to approximately zero. As such, by stopping the two groups of ultrasonic transducers 28 in a step-wise manner, the concentration of the mist 62 in the furnace 12 can be gently decreased at end of the epitaxial growth step.

At the end of the epitaxial growth step, since the mist 62 is no longer supplied to the substrate 70, the heat of the substrate 70 is no longer drawn away by the mist 62. Consequently, the temperature of the substrate 70 increases. Even though the supply of the mist 62 has stopped, the solution 60 still adheres to the surface of the substrate 70, and the film continues to grow until this solution 60 is solidified. There may be a case where a rapid drop in the concentration of the mist 62 in the furnace 12 causes a rapid rise in temperature of the substrate 70, resulting in a film to be grown having undesired characteristics. In contrast to this, by gently decreasing the concentration of the mist 62 in the furnace 12 at the end of the epitaxially-growing step, as described above, the temperature of the substrate 70 will gently rise, resulting in the film having stable characteristics. It should be noted that, at the end of the epitaxial growth step, either of the ultrasonic transducers 28a and the ultrasonic transducers 28b may be stopped prior to the other.

As described above, at the beginning or the end of the epitaxial growth step, the temperature of the substrate 70 can be gently changed by gently changing the concentration of the mist 62, and accordingly a film of higher quality can be formed.

### Third Embodiment

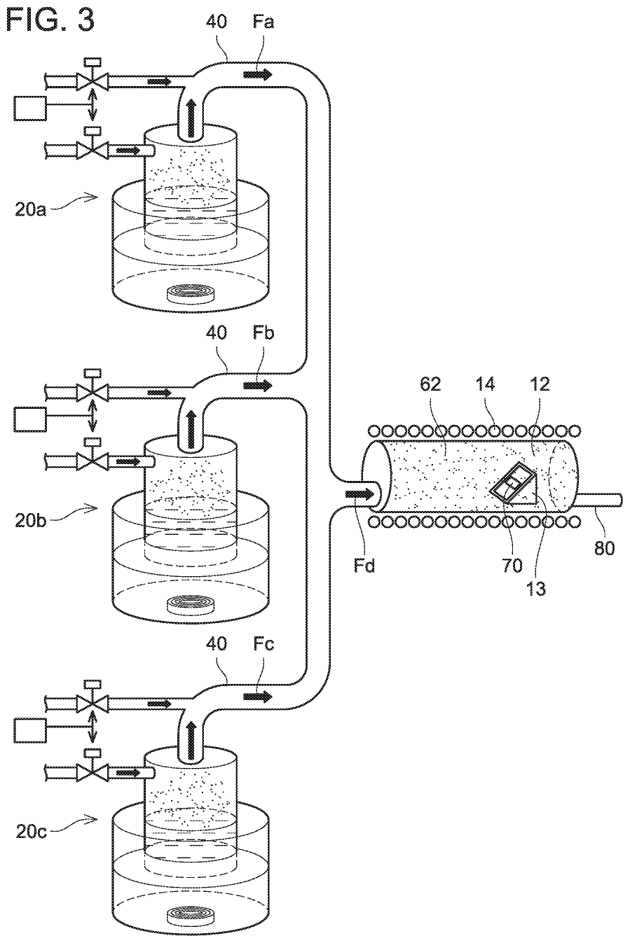

As shown in FIG. 3, a film formation apparatus in a third embodiment comprises three mist supply apparatuses 20a to 20c. Each of the mist supply apparatuses 20a to 20c has a configuration equal to the configuration of the mist supply apparatus 20 in the first embodiment. The mist supply apparatuses 20a to 20c respectively include mist supply paths 40, downstream portions of which are merged into one and connected to a furnace 12. In the third embodiment, gas flow controllers 46 operate such that a total flow rate Fd of a flow rate Fa of gas that flows through the mist supply path 40 of the mist supply apparatus 20a, a flow rate Fb of gas that flows through the mist supply path 40 of the mist supply apparatus 20b, and a flow rate Fe of gas that flows through the mist supply path 40 of the mist supply apparatus 20c (i.e., a flow rate of gas supplied to the furnace 12) is constant. Each of the flow rates Fa, Fb, and Fc may be controlled to be constant to provide a constant total flow rate Fd. Alternatively, during the epitaxial growth step, a ratio between the flow rate Fa, the flow rate Fb, and the flow rate Fe may be controlled to change while the total flow rate Fd is kept constant. By making the total flow rate Fd constant, the flow velocity of the mist 62 in the furnace 12 becomes constant, thereby the characteristics of the film to be grown can be controlled accurately.

Some of the features characteristic disclosed herein will be listed as below. It should be noted that the respective technical elements are independent of one another, and are useful solely or in combinations.

In an example of the film formation apparatus disclosed herein, the gas flow rate controller may be configured to increase the flow rate of the diluent gas when decreasing the flow rate of the carrier gas.

According to this configuration, the concentration of the mist in the furnace can be decreased while changes in the flow velocity of the mist in the furnace are suppressed.

In an example of the film formation apparatus disclosed herein, the mist generation tank may comprise: a reservoir storing the solution; a first ultrasonic transducer configured to apply ultrasonic vibration to the solution in the reservoir so as to generate the mist of the solution in the reservoir; and a second ultrasonic transducer configured to apply ultrasonic vibration to the solution in the reservoir so as to generate the mist of the solution in the reservoir, and the film formation apparatus may be configured, at a beginning of the epitaxial growth of the film, to activate the first ultrasonic transducer at first, and then additionally activate the second ultrasonic transducer.

According to the above configuration, the concentration of the mist supplied to the furnace can be gradually increased at the beginning of the epitaxial growth of the film. The characteristics of the film at the beginning of the epitaxial growth can thereby be controlled accurately.

The film formation apparatus disclosed herein in an example may be configured, at an end of the epitaxial growth of the film, to stop one of the first ultrasonic transducer and the second ultrasonic transducer at first, and then additionally stop the other of the first ultrasonic transducer and the second ultrasonic transducer.

According to this configuration, the concentration of the mist supplied to the furnace can be gradually decreased at the end of the epitaxial growth of the film. The characteristics of the film at the end of the epitaxial growth can be thereby controlled accurately.

In an example of the film formation apparatus disclosed herein, the mist generation tank may comprise a plurality of mist generation tanks, and the gas flow rate controller may be configured to control respective flow rates of gas flowing from each mist generation tank to the furnace such that a total flow rate of gas flowing from the plurality of mist generation tanks to the furnace is constant.

According to this configuration, the film can be epitaxially grown stably.

Specific examples of the present disclosure have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A film formation apparatus configured to supply mist of a solution to a surface of a substrate so as to epitaxially grow a film on the surface of the substrate, the film formation apparatus comprising:
a furnace configured to house the substrate so as to heat the substrate;
a mist generation tank configured to generate the mist of the solution therein;
a mist supply path connecting the mist generation tank and the furnace;
a carrier gas supply path configured to supply carrier gas into the mist generation tank;
a diluent gas supply path configured to supply diluent gas into the mist supply path; and
a gas flow rate controller configured to control a flow rate of the carrier gas and a flow rate of the diluent gas,
wherein
the mist in the mist generation tank flows to the mist supply path with the carrier gas,
the mist in the mist supply path flows to the furnace with the carrier gas and the diluent gas, and
the gas flow rate controller is configured to decrease the flow rate of the diluent gas when increasing the flow rate of the carrier gas.

2. The film formation apparatus of claim 1, wherein the gas flow rate controller is configured to increase the flow rate of the diluent gas when decreasing the flow rate of the carrier gas.

3. The film formation apparatus of claim 1, wherein
the mist generation tank comprises:
a reservoir storing the solution;
a first ultrasonic transducer configured to apply ultrasonic vibration to the solution in the reservoir so as to generate the mist of the solution in the reservoir, and
a second ultrasonic transducer configured to apply ultrasonic vibration to the solution in the reservoir so as to generate the mist of the solution in the reservoir, and
the film formation apparatus is configured, at a beginning of the epitaxial growth of the film, to activate the first ultrasonic transducer at first, and then additionally activate the second ultrasonic transducer.

4. The film formation apparatus of claim 3, wherein the film formation apparatus is configured, at an end of the epitaxial growth of the film, to stop one of the first ultrasonic transducer and the second ultrasonic transducer at first, and then additionally stop the other of the first ultrasonic transducer and the second ultrasonic transducer.

5. The film formation apparatus of claim 1, wherein
the mist generation tank comprises a plurality of mist generation tanks, and
the gas flow rate controller is configured to control respective flow rates of gas flowing from each mist generation tank to the furnace such that a total flow rate of gas flowing from the plurality of mist generation tanks to the furnace is constant.
